(19) United States
(12) Patent Application Publication
(10) Pub. No.: US 2010/0052958 A1
(43) Pub. Date: Mar. 4, 2010

(54) SAMPLE-DEPENDENT AMPLIFICATION OF MAGNETIC RESONANCE SIGNAL

(75) Inventors: Henricus Gerardus Roeven, Eindhoven (NL); Johannes Hendrik Boef, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/520,187

(22) PCT Filed: Dec. 21, 2007
(86) PCT No.: PCT/IB2007/055273

§ 371 Date: Jun. 19, 2009

(30) Foreign Application Priority Data
Dec. 22, 2006 (EP) 06126957.7

(51) Int. Cl. H03M 1/00; H03M 1/12

(52) U.S. Cl. 341/139; 341/155

(57) ABSTRACT

A digitizer for digitizing a magnetic resonance (MR) signal is hereby disclosed, the digitizer comprising at least two analog amplifiers (102₁, 102₂ . . . 102ₙ) electrically connected in parallel and configured to amplify the MR signal, wherein each analog amplifier has a different analog gain value, a measuring unit configured to measure a characteristic of the MR signal, a sample selection module (108) configured to generate a selection signal (SS) based on the measured characteristic, and a first analog-to-digital converter (104) configured to digitize the amplified MR signal from one of the at least two analog amplifiers, based on the selection signal.

### FIELD OF THE INVENTION

The invention relates to the field of magnetic resonance (MR), particularly to digitizers used in an MR system.

### BACKGROUND OF THE INVENTION

The United States patent U.S. Pat. No. 6,621,433B1 discusses a receiver for a resonance signal of an MR imaging system, wherein the receiver generates a baseband signal for image processing by dividing a raw resonance signal among multiple parallel channels, each being amplified at a respective gain. A digital channel selector determines, at any given moment, a lowest-distortion channel to be further processed. Amplitude and phase error compensation are handled digitally using complex multipliers, which are derived by a calibration, based on a simple Larmor oscillator, which can be done without the need for a sample and without repeating when measurement conditions are changed.

In a particular embodiment, a gain setting module controls a switch to select an amplified signal from the plurality of amplified signals according to a gain table. The gain table is created via a gain table calibration procedure that correlates the peak resonance signal amplitude with phase encoding level.

### SUMMARY OF THE INVENTION

In the prior art, the gain setting selected for a particular phase encoding level is constant during the particular profile. Such a method of setting a constant gain during a particular profile could yield sub-optimal results in the final image, as variations in the intensity of MR signal acquired during a particular phase encoding level cannot be accounted for. It is thus desirable to have a digitizer for digitizing an MR signal, wherein the digitizer is capable of varying the gain setting during a particular phase-encoding level as well.

Accordingly, a digitizer for digitizing an MR signal is hereby disclosed, the digitizer comprising at least two analog amplifiers electrically connected in parallel and configured to amplify the MR signal, wherein each analog amplifier has a different analog gain value; a measuring unit configured to measure a characteristic of the MR signal; a sample selection module configured to generate a selection signal based on the measured characteristic; and a first analog-to-digital converter (ADC) configured to digitize the amplified MR signal from one of the at least two analog amplifiers, based on the selection signal.

A characteristic of the MR signal, for example its amplitude, signal-to-noise ratio (SNR), etc., is measured by a measuring unit. In a typical MR acquisition, the signal amplitude changes both in between different phase encode levels as well as within a particular phase encode level. An example of the latter is the case where an echo signal is being acquired. For each phase encode level, the echo will start at or near the noise level, increase to a certain maximum and decrease again to or below noise level. By measuring the signal amplitude or SNR, and selecting the analog amplifier with an appropriate gain setting based on the measured characteristic, the entire MR signal can be digitized more accurately. Such a method of setting the gain based on the measured characteristic may be called “sample-dependent amplification”.

In addition to a digitizer for digitizing an MR signal, a method of digitizing an MR signal is also disclosed herein, the method comprising amplifying the MR signal using one or more of at least two analog amplifiers that are electrically connected in parallel, wherein each analog amplifier has a different analog gain value; measuring a characteristic of the MR signal; generating a selection signal based on the measured characteristic; selecting one of the at least two analog amplifiers based on the selection signal; and digitizing the MR signal from the selected analog amplifier using a first ADC.

Furthermore, a computer program for digitizing an MR signal is also disclosed herein, the computer program comprising instructions for amplifying the MR signal using one or more of at least two analog amplifiers that are electrically connected in parallel, wherein each analog amplifier has a different analog gain value; measuring a characteristic of the MR signal; generating a selection signal based on the measured characteristic; selecting one of the at least two analog amplifiers based on the selection signal; and digitizing the MR signal from the selected analog amplifier using a first ADC.

### BRIEF DESCRIPTION OF THE DRAWINGS

These and other aspects will be described in detail hereinafter, by way of example, on the basis of the following embodiments, with reference to the accompanying drawings, wherein:

FIG. 1 schematically shows an embodiment of a digitizer as disclosed herein, wherein a characteristic of an MR signal is measured and used to select an appropriate gain value in the digitizer;

FIG. 2 schematically shows an embodiment of the digitizer implemented using multiple ADCs;

FIG. 3 schematically shows an MR system utilizing the digitizer as disclosed herein; and

FIG. 4 shows a method of digitizing an MR signal as disclosed herein.

Corresponding reference numerals when used in the various figures represent corresponding elements in the figures.

### DETAILED DESCRIPTION OF EMBODIMENTS

MR signals have a wide dynamic range, i.e., the signal intensity varies by a large amount, often 2 or more orders of magnitude, during an acquisition. In order to avoid saturation effects and reduce quantization noise, it is important to have a digitizer that can handle such a wide dynamic range while converting analog MR signals into a digital representation.

In order to minimize quantization noise introduced by the ADC, the analog gain value of the analog amplifier needs to be adjusted to utilize the full dynamic range of the ADC. However, a single fixed gain receiver implemented with readily available (off-the-shelf) ADC components may still introduce an unacceptable level of quantization noise, especially when the SNR is low. Thus, some form of variable gain is required. An approach to achieving such variable gain setting is to have multiple analog amplifiers, each of which is assigned a different gain value corresponding to an operating range with an acceptable quantization noise level. The output of one of the multiple analog amplifiers is then selected based on the optimal operating range.

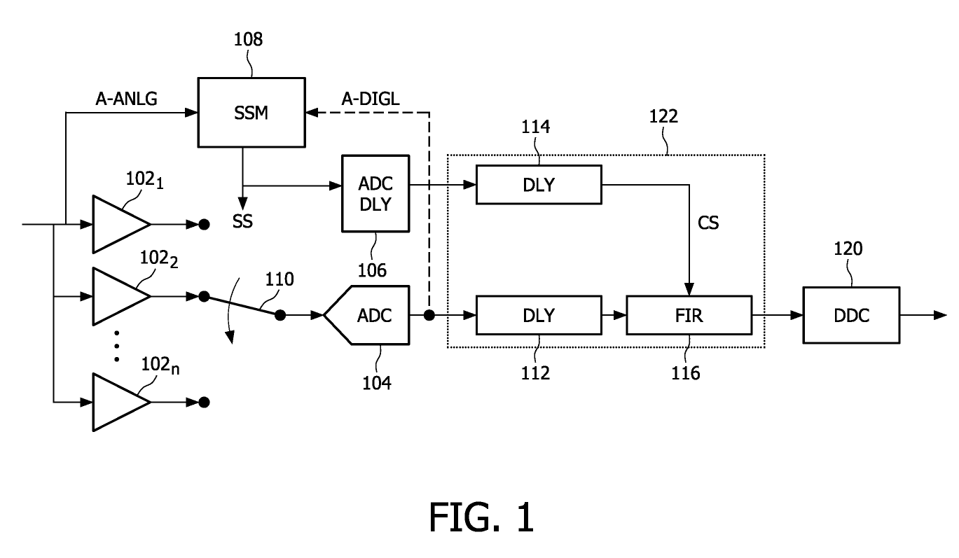

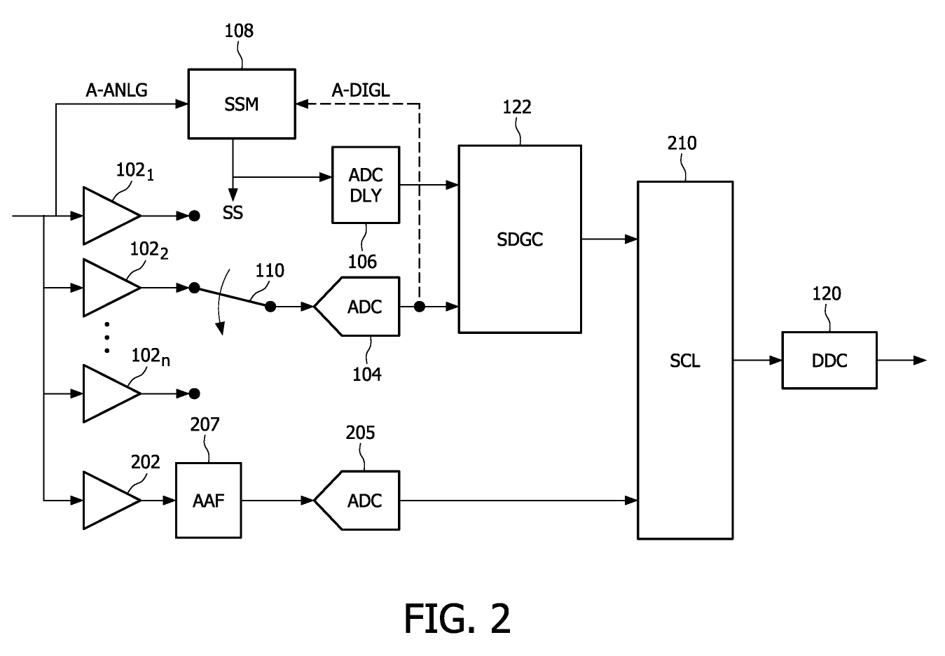

This document discusses another implementation of a radio-frequency (RF) digital receiver topology that has a suitably wide dynamic range. The topology, based on a Direct Digital Receiver (DDR), consists of one or more analog RF amplifiers that match the dynamic gain of the MR signal to that of the digitizer, an ADC that samples the MR signal directly (i.e., without mixing to an intermediate frequency) and a Digital Down Converter (DDC) that matches the sample rate of the sampled signal to that of the MR signal bandwidth by demodulating it to base band frequency combined with digital filtering techniques. The resulting implementations of the digitizer, as explained below with reference to FIGS. 1 and 2, have a wide dynamic range that enables the digitizer to digitize high-dynamic-range MR signals more accurately. This particular topology, wherein the sample selection occurs before digitization also has the advantages of high sensitivity to delay mismatches (i.e., analog phase), low power dissipation, no variation with temperature and low digital gate count, but it may be more complex that some other topologies to implement.

In general, there are many possible methods to select the correct gain value for the digitizer. One such method is the “profile dependent amplification” (PDA) method, wherein the gain value is selected based on the phase-encoding level and remains constant during the particular phase encoding level. Further information about the PDA method may be obtained from the United States patent U.S. Pat. No. 5,023,552. The PDA method may be improved upon by taking into account the expected change in signal strength and/or SNR of the MR signal. For instance, the MR signal is often received as a refocused echo; the process of refocusing together with the normal process of acquiring data using a readout gradient dictates that the signal intensity of the refocused echo will start at noise level, increase to a maximum around the center of the readout gradient pulse and drop back to noise level. The increase and decrease in the signal intensity normally follows a mono or multi-exponential curve and may be calculated using a prediction model which takes into account image acquisition parameters like type of acquisition (two-dimensional vs. three-dimensional), type of pulse sequence (spin-echo vs. fast field echo), pulse sequence parameters (echo time or TE, repetition time or TR), etc. Thus the envelope of the change of signal intensity is known. Therefore, the gain setting can be changed in a predetermined fashion during a particular phase encoding level based on a mathematical model of the expected change in signal intensity.

A more accurate method is to set the gain based on actual or measured signal levels. As shown in FIG. 1, the actual signal levels may be measured either before the analog signal is converted into digital format by the ADC or after. The former measurement is shown by the solid line A-ANLG while the latter is shown by the dotted line A-DIGL. The MR signal is received by various analog amplifiers 102₁, 102₂ . . . 102ₙ connected in parallel, and amplified according to the respective analog gain settings of the various analog amplifiers. A sample selection module (SSM) 108 generates a selection signal SS to control a switch 110 to select the output of the most appropriate analog amplifier. A first ADC 104 receives the selected, amplified analog signal and converts it into a digital representation. The selection signal SS is also supplied to a delay matching circuit 106 that matches the delay introduced by the signal selection module 108 and the delay introduced by the first ADC 104. The sample delay and gain compensation unit 122, consisting of delay lines 112, 114 and a finite impulse response (FIR) filter 116, receives both the digitized MR signal from the ADC and the delay matching signal from the delay matching circuit 106, and outputs signals to a digital down-converter (DDC) 120.

Measuring the characteristic (for example, intensity or SNR) of the analog MR signal and supplying it to the sample selection module 108, as denoted by the arrow A-ANLG, provides a “fast” implementation of the digitizer as disclosed herein. This particular implementation is termed “fast”, as the response time will generally be faster than an implementation that involves measuring the characteristic of the MR signal after conversion to digital format. Furthermore, the latter implementation may also limit the bandwidth of the signal to be acquired due to delays in the ADC and sample selection logic. The “fast” implementation may typically consist of a peak detector having a short attack time and relaxed decay time, to detect the envelope of the analog signal.

In order to process the selected samples in the digital domain, the delay of each ADC channel in a single receiver should be matched. If there are multiple channels, the delays in the various channels need to be matched as well. The delay can be controlled in unit sample clocks (shown as “delay lines” 112, 114) plus a sub-sample delay time which is implemented as the FIR filter 116.

Samples from different analog amplifiers with different gain settings also need to be aligned or scaled in amplitude. Such scaling may be done by selecting different sets of coefficients from a coefficient bank in the FIR filter 116. The coefficients can be programmed according to the actual gain of each amplifier in the channel (as determined by the measured signal intensity or SNR), based on the selection signal SS generated by the sample selection module 108, which is in turn generated based on the measured characteristic denoted by A-ANLG or A-DIGL. The information as to which particular sample has been selected, i.e., which analog amplifier has been connected by the switch 110 to the first ADC 104, is transported along with the sample data via an ADC-delay matching circuit 106 and used to select the coefficients of the FIR filter 116 on a sample-by-sample basis, as denoted by the coefficient select signal CS. The ADC-delay matching circuit 106 is used to match the additional delay introduced by the first ADC during the process of digitization, which varies depending on the gain setting of the selected analog amplifier. Thus, in each case the information about which gain setting (i.e., which analog amplifier) has been selected must be communicated to the digital domain in order to select the proper FIR filter coefficients.

FIG. 2 shows an embodiment of the digitizer consisting of two separate ADCs with fixed gain in the “fine” path and selectable gain in the “coarse” path. In this embodiment, in addition to the multiple analog amplifiers 102₁, 102₂ . . . 102ₙ connected in parallel as in the embodiment of FIG. 1, an additional analog amplifier 202 is also connected in parallel to the multiple analog amplifiers 102₁, 102₂ . . . 102ₙ. The output of the additional analog amplifier is connected to a second ADC 205 via an anti-aliasing filter (AAF) 207. The outputs of both the sample gain and delay compensation (SGDC) circuit 122 and the second ADC 205 are supplied for down-conversion to a DDC 120 via a sample selection and scaling (SCL) circuit 210.

The second ADC 205 is considered to be in the “high gain” or “fine” path of the digitizer. Due to the anti-aliasing filter 207, mirror frequencies that might otherwise interfere with the principle of sub-sampling are suppressed. Since the signal band of interest is relatively narrow, band-limited sub-sampling can be employed, but noise at mirror frequencies need to be suppressed sufficiently. A steep anti-aliasing filter however, precludes the use of automatic gain selection in the analog domain, since in a practical implementation the filter is between the amplifier and the ADC. The response time of such a filter may be too long to allow selection of gain per sample.

The other ADCs 102₁, 102₂ . . . 102ₙ may be considered to be in the “low gain” or “coarse” path of the digitizer. Since gain levels are lower in this path, the quantization noise of the ADC becomes dominant. As a result, no anti-aliasing filter is required. Consequently, the time required for selecting the correct gain is much shorter. Employing (automatic) dynamic gain selection in this path improves the SNR of large amplitude samples, and by this reduces visible artifacts in the resulting image.

One advantage of the various embodiments disclosed herein is that since the delays of the various analog amplifiers are matched, the automatically selected gain settings produce equidistant samples in k-space from the ADC, which operates independent of the actual gain setting. Both amplitude (gain) and phase (delay) correction are performed before demodulation, so as to allow a single digital demodulator 120 to operate on a continuous stream of equidistantly spaced samples (in k-space) of constant gain. This gain and delay correction requires a one-time calibration where the exact analog propagation delay and gain are measured. An advantage of this method over a gain correction before the delay compensation is that the bit width of the interface between the ADC and digital domain does not increase but remains equal to the ADC bit width. The only additional information required to be transmitted is a few bits for selection info, which can be combined for multiple channels.

It may be noted that gain correction is required for matching samples coming from different analog amplifiers in a single digitizer. Additionally, delay compensation may be required to match samples coming from different ADCs within a single digitizer, or from different digitizers. In the single ADC topologies, the additional delay compensation is not required. In the embodiments proposed herein, the FIR filter provides an efficient way to implement both the gain and delay compensations mentioned above.

It may also be noted that the additional analog amplifier in the coarse path may have fixed or variable analog gain. Though only embodiments with single and dual ADCs are shown, it is possible to extend the concept disclosed herein to cover embodiments consisting of more than two ADCs as well.

Automatic selection on a sample-by-sample basis requires very good delay matching in the analog front-end. Delay differences between the gain settings before a single ADC must be sufficiently small. In case of temperature dependencies (delay differences between channels or between receivers vary over operational temperature range) it might be required to measure the actual temperature and, based on a model of the delay change, correct for this difference in the FIR filter coefficients. This approach is only applicable to multi-ADC topologies, for example as shown in FIG. 2.

The embodiments of the digitizer disclosed herein thus provide automatic or semi-automatic gain selection at the analog input, and correction of gain (in the case of single ADC topologies) or both gain and delay (in the case of multi-ADC topologies) in the digital domain. Considered as a unit, such a digitizer delivers digital samples with almost constant gain and a large dynamic range.

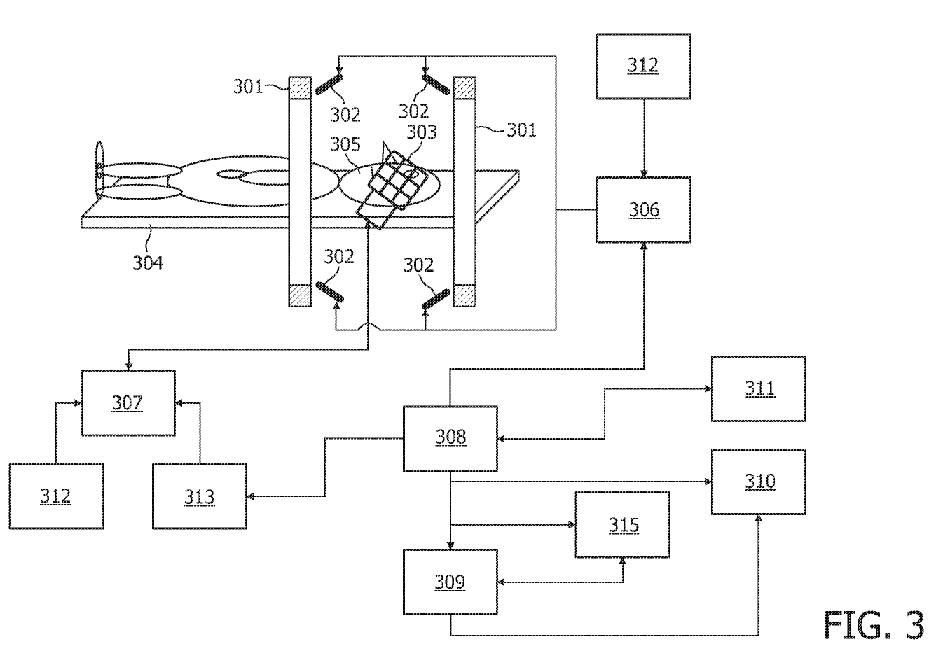

FIG. 3 shows a possible embodiment of an MR system utilizing the digitizer as disclosed herein. The MR system comprises a set of main coils 301, multiple gradient coils 302 connected to a gradient driver unit 306, and RF coils 303 connected to an RF coil driver unit 307. The function of the RF coils 303, which may be integrated into the magnet in the form of a body coil, or may be separate surface coils, is further controlled by a transmit/receive (T/R) switch 313. The multiple gradient coils 302 and the RF coils are powered by a power supply unit 312. A transport system 304, for example a patient table, is used to position a subject 305, for example a patient, within the MR imaging system. A control unit 308 controls the RF coils 303 and the gradient coils 302. The control unit 308, though shown as a single unit, may be implemented as multiple units as well. The control unit 308 further controls the operation of a reconstruction unit 309. The control unit 308 also controls a display unit 310, for example a monitor screen or a projector, a data storage unit 315, and a user input interface unit 311, for example, a keyboard, a mouse, a trackball, etc.

The main coils 301 generate a steady and uniform static magnetic field, for example, of field strength 1T, 1.5T or 3T. The disclosed digitizer may be employed at other field strengths as well. The main coils 301 are arranged in such a way that they typically enclose a tunnel-shaped examination space, into which the subject 305 may be introduced. Another common configuration comprises opposing pole faces with an air gap in between them into which the subject 305 may be introduced by using the transport system 304. To enable MR imaging, temporally variable magnetic field gradients superimposed on the static magnetic field are generated by the multiple gradient coils 302 in response to currents supplied by the gradient driver unit 306. The power supply unit 312, fitted with electronic gradient amplification circuits, supplies currents to the multiple gradient coils 302, as a result of which gradient pulses (also called gradient pulse waveforms) are generated. The control unit 308 controls the characteristics of the currents, notably their strengths, durations and directions, flowing through the gradient coils to create the appropriate gradient waveforms. The RF coils 303 generate RF excitation pulses in the subject 305 and receive MR signals generated by the subject 305 in response to the RF excitation pulses. The RF coil driver unit 307 supplies current to the RF coil 303 to transmit the RF excitation pulse, and amplifies the MR signals received by the RF coil 303. The transmitting and receiving functions of the RF coil 303 or set of RF coils are controlled by the control unit 308 via the T/R switch 313. The T/R switch 313 is provided with electronic circuitry that switches the RF coil 303 between transmit and receive modes, and protects the RF coil 303 and other associated electronic circuitry against breakthrough or other overloads, etc. The characteristics of the transmitted RF excitation pulses, notably their strength and duration, are controlled by the control unit 308.

It is to be noted that though the transmitting and receiving coil are shown as one unit in this embodiment, it is also possible to have separate coils for transmission and reception, respectively. It is further possible to have multiple RF coils 303 for transmitting or receiving or both. The RF coils 303 may be integrated into the magnet in the form of a body coil, or may be separate surface coils. They may have different geometries, for example, a birdcage configuration or a simple loop configuration, etc. The control unit 308 is preferably in the form of a computer that includes a processor, for example a microprocessor. The control unit 308 controls, via the T/R switch 313, the application of RF pulse excitations and the reception of MR signals comprising echoes, free induction decays, etc. User input interface devices 311 like a keyboard, mouse, touch-sensitive screen, trackball, etc., enable an operator to interact with the MR system.

The MR signal received with the RF coils 303 contains the actual information concerning the local spin densities in a region of interest of the subject 305 being imaged. The received MR signals are digitized by the digitizer disclosed herein and transmitted to the reconstruction unit 309. The reconstruction unit 309 reconstructs one or more MR images or spectra from the received signals, and displays them on the display unit 310. It is alternatively possible to store the signal from the reconstruction unit 309 in a storage unit 315, while awaiting further processing. The reconstruction unit 309 is constructed advantageously as a digital image-processing unit that is programmed to derive the MR signals received from the RF coils 303.

The control unit 308 is capable of loading and running a computer program comprising instructions that, when executed on the computer, enable the computer to execute the various aspects of the methods disclosed herein. The computer program disclosed herein may reside on a computer readable medium, for example a CD-ROM, a DVD, a floppy disk, a memory stick, a magnetic tape, or any other tangible medium that is readable by the computer. The computer program may also be a downloadable program that is downloaded, or otherwise transferred to the computer, for example via the Internet. The transfer means may be an optical drive, a magnetic tape drive, a floppy drive, a USB or other computer port, an Ethernet port, etc.

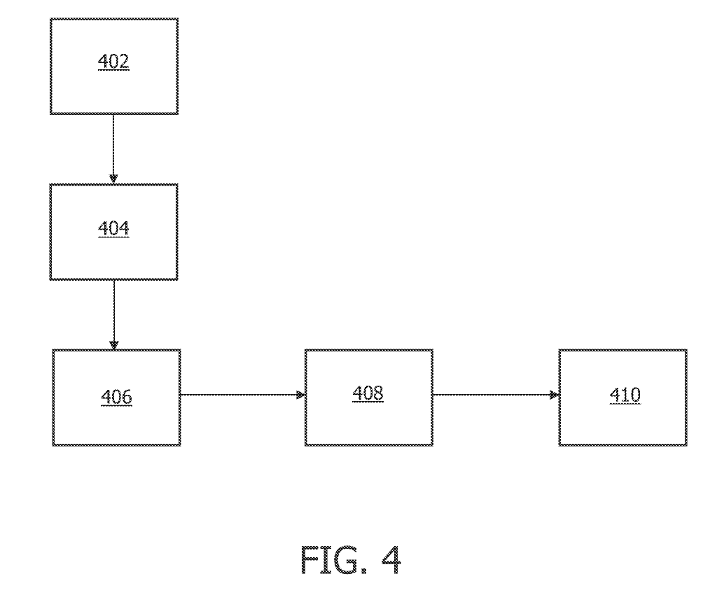

FIG. 4 shows a method of digitizing an MR signal, as disclosed herein. The method involves the steps of amplifying the magnetic resonance signal (402) using one or more of at least two analog amplifiers that are electrically connected in parallel, wherein each analog amplifier has a different analog gain value, measuring a characteristic (404) of the magnetic resonance signal, generating a selection signal (406) based on the measured characteristic, selecting one of the at least two analog amplifiers (408) based on the selection signal, and digitizing the magnetic resonance signal (410) from the selected analog amplifier using a first analog-to-digital converter.

The order in the described implementations of the disclosed methods is not mandatory. A person skilled in the art may change the order of steps or perform steps concurrently using threading models, multi-processor systems or multiple processes without departing from the disclosed concepts.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A digitizer for digitizing a magnetic resonance signal, comprising:
at least two analog amplifiers electrically connected in parallel and configured to amplify the magnetic resonance signal, wherein each analog amplifier has a different analog gain value;
a measuring unit configured to measure a characteristic of the magnetic resonance signal;
a sample selection module configured to generate a selection signal based on the measured characteristic; and
a first analog-to-digital converter configured to digitize the amplified magnetic resonance signal from one of the at least two analog amplifiers, based on the selection signal.

2. A digitizer for digitizing a magnetic resonance signal as claimed in claim 1, wherein the measuring unit is configured to measure the characteristic of the magnetic resonance signal during a single phase-encoding step.

3. A digitizer for digitizing a magnetic resonance signal as claimed in claim 1, wherein the measured characteristic is an amplitude of the magnetic resonance signal prior to amplification by the at least two analog amplifiers.

4. A digitizer for digitizing a magnetic resonance signal as claimed in claim 1, wherein the measured characteristic is a signal-to-noise ratio of the magnetic resonance signal prior to amplification by the at least two analog amplifiers.

5. A digitizer for digitizing a magnetic resonance signal as claimed in claim 1, wherein the measuring unit measures the characteristic of the magnetic resonance signal at the output of the first analog-to-digital converter.

6. A digitizer for digitizing a magnetic resonance signal as claimed in claim 1, further comprising:
an additional analog amplifier electrically connected in parallel to the at least two analog amplifiers, wherein the additional analog amplifier is configured to amplify the magnetic resonance signal;
an anti-aliasing filter configured to filter the amplified magnetic resonance signal from the additional analog amplifier to generate a filtered signal; and
a second analog-to-digital converter configured to digitize the filtered signal.

7. A magnetic resonance system including a digitizer for digitizing a magnetic resonance signal as claimed in claim 1, the magnetic resonance system comprising:
a radio-frequency receive coil to receive the magnetic resonance signal from a subject under examination;
at least two analog amplifiers electrically connected in parallel to the radio-frequency receive coil and configured to amplify the magnetic resonance signal, wherein each analog amplifier has a different analog gain value;
a measuring unit to measure a characteristic of the magnetic resonance signal;
a sample selection module configured to generate a selection signal based on the measured characteristic; and
a first analog-to-digital converter configured to digitize the amplified magnetic resonance signal from one of the at least two analog amplifiers, based on the selection signal.

8. A method of digitizing a magnetic resonance signal, the method comprising:
amplifying the magnetic resonance signal using one or more of at least two analog amplifiers that are electrically connected in parallel, wherein each analog amplifier has a different analog gain value;
measuring a characteristic of the magnetic resonance signal;
generating a selection signal based on the measured characteristic;
selecting one of the at least two analog amplifiers based on the selection signal; and
digitizing the magnetic resonance signal from the selected analog amplifier using a first analog-to-digital converter.

9. A computer program for digitizing a magnetic resonance signal, the computer program comprising instructions for:
amplifying the magnetic resonance signal using one or more of at least two analog amplifiers that are electrically connected in parallel, wherein each analog amplifier has a different analog gain value;
measuring a characteristic of the magnetic resonance signal;
generating a selection signal based on the measured characteristic;
selecting one of the at least two analog amplifiers based on the selection signal; and
digitizing the magnetic resonance signal from the selected analog amplifier using a first analog-to-digital converter.
